(19) United States
(12) Patent Application Publication
(10) Pub. No.: US 2003/0066484 A1
(43) Pub. Date: Apr. 10, 2003

(54) Electrode cover, plasma apparatus utilizing the cover, and method of fitting the cover onto the plasma electrode

(75) Inventors: Tatsuya Morikage, Mihama-ku (JP); Katsuyoshi Hagiwara, Mihama-ku (JP)

Correspondence Address: OLIFF & BERRIDGE, PLC, P.O. BOX 19928, ALEXANDRIA, VA, 22320, US

(73) Assignee: Kawasaki MIcroelectronics, Inc., Mihama-ku (JP)

(21) Appl. No.: 10/253,431

(22) Filed: Sep. 25, 2002

(30) Foreign Application Priority Data
Sep. 26, 2001 (JP) 2001-293188

(51) Int. Cl. C23F 1/00; C23C 16/00

(52) U.S. Cl. 118/723 E; 118/728; 156/345.51; 156/345.47

(57) ABSTRACT

A cover for an electrode of a plasma apparatus and the plasma apparatus utilizing the cover. Moreover, a method of fitting the cover onto the electrode. The electrode has a raised central portion surrounded by a sidewall and a peripheral portion. The cover includes a plurality of divided sections. The divided sections are fitted to the peripheral portion of the electrode from the sides. A clearance between the inner wall of the cover and the sidewall of the electrode may be reduced, and the etching of the sidewall of the electrode is suppressed.

### BACKGROUND OF THE INVENTION

1. Field of Invention

This invention relates to an electrode cover for covering a peripheral portion of an electrode used in a plasma apparatus, and to the apparatus utilizing the cover. This invention also relates to a method of fitting the cover to the electrode.

2. Description of Related Art

In plasma apparatuses such as plasma etching apparatus, an electrode is used for generating plasma. A workpiece, such as a semiconductor wafer, is placed on the electrode during the processing by the plasma apparatus. A peripheral portion of the electrode not covered by the workpiece is also processed, or etched, during the processing of the workpiece. Accordingly, a cover for covering the peripheral portion of the electrode has been commonly used.

Typically, the main surface of the electrode has a raised central portion or a pedestal surrounded by a sidewall, and a peripheral portion around the raised portion. The peripheral portion is connected to the raised portion by the sidewall. The workpiece to be processed in the plasma apparatus is placed on the raised central portion. Generally, the cover is a ring-shaped disk having an opening corresponding to the central portion of the electrode.

In order to minimize the damage of the electrode, the opening of the cover should have essentially the same shape and size of the central portion of the electrode. However, the opening should have a certain clearance around the sidewall around the central portion of the electrode so that the cover can be fitted to the electrode. In practice, the clearance should not be too small so that the sidewall of the electrode is not damaged during fitting of the cover.

When the clearance is too large, on the other hand, the sidewall of the electrode is damaged during operation of the plasma apparatus, i.e., successive processing of a plurality of workpieces. Therefore, the conventional cover for an electrode is not effective enough to sufficiently prevent the damage of the electrode.

Various improvements in covers for plasma apparatus have been proposed in, for example, Japanese Unexamined Patent Application Publication Nos. 62-78845, 1-312087 (U.S. Pat. No. 4,968,374), 7-245292 (U.S. Pat. No. 5,556,500), 8-227934 (U.S. Pat. No. 5,762,714), 10-64989 (U.S. Pat. No. 5,748,434), 10-144657, 11-74099 (U.S. Pat. No. 5,942,039), 11-181565, 11-186234, and 2000-173931. However, none of these references address this fundamental problem.

### SUMMARY OF THE INVENTION

Accordingly, in order to solve the above-described problems of the known art, an object of the present invention is to provide a cover for effectively protecting the electrode from the plasma.

The cover in accordance with exemplary embodiments of the invention can include a plurality of divided sections, wherein the cover, when fitted to the electrode, has an inner edge that surrounds the sidewall of the electrode and that is formed by combining the divided sections, the divided sections keeping a fixed positional relationship with each other during an operation of the plasma apparatus.

The cover in accordance with another aspect of exemplary embodiments of the invention can include a plurality of divided sections, wherein the cover, when fitted to the electrode, has an inner edge that surrounds the sidewall of the electrode and that is formed by combining the divided sections, the inner edge having an upper surface lower than the back surface of the workpiece supported on the central portion of the electrode.

The cover in accordance with still another aspect of exemplary embodiments of the invention can include a plurality of divided sections including a plurality of inner sections and an outer section, wherein the cover, when fitted to the electrode, includes an inner portion having an inner edge that surrounds the sidewall of the electrode and an outer portion. The inner edge is formed by combining the inner sections, and the outer portion is formed by combining the outer section to the combined inner sections.

Furthermore, a plasma apparatus for processing a workpiece in accordance with exemplary embodiments of the invention is also provided, and can include an electrode having a main surface that has a raised central portion for supporting the workpiece during the processing, a sidewall that surrounds the central portion and a peripheral portion connected to the central portion by the sidewall. Moreover, the cover that covers the peripheral portion of the main surface of the electrode includes an inner edge that surrounds the sidewall of the electrode.

The cover of the apparatus can also include a plurality of divided sections, wherein the inner edge of the cover is formed by combining the divided sections, and the divided sections keep a fixed positional relationships with each other during an operation of the plasma apparatus.

The cover of the apparatus in accordance with another aspect of exemplary embodiments of the invention can also include a plurality of divided sections, wherein the inner edge of the cover is formed by combining the divided sections and the inner edge has an upper surface lower than the back surface of the workpiece supported on the central portion of the electrode.

The cover of the apparatus in accordance with still another aspect of exemplary embodiments of the invention can also include a plurality of divided sections including a plurality of inner sections and an outer section, wherein the inner edge of the cover is formed by combining the divided inner sections and the outer section is combined to an outside of the combined inner sections.

Finally, a method of fitting a cover to an electrode of a plasma apparatus in accordance with exemplary embodiments of the invention is also provided. The method can include the steps of providing a plurality of divided sections for the cover, and fitting the cover to the electrode by moving the plurality of divided sections toward the sidewall of the electrode so that the plurality of divided sections are combined with each other to form an inner edge of the cover that surrounds the sidewall of the electrode.

### BRIEF DESCRIPTION OF THE DRAWINGS

FIG. 1 is an exemplary schematic diagram showing a plasma etching apparatus including a cover for a plasma electrode according to an embodiment of this invention;

FIG. 2 is an exemplary schematic diagram showing the cover and a method of placing the cover over a lower electrode according to the embodiment of this invention;

FIG. 3 is an exemplary schematic diagram showing a state in which the cover according to the embodiment of this invention is placed over the lower electrode;

FIG. 4 is an exemplary schematic diagram showing an example of a lower electrode and a cover in a conventional plasma apparatus;

FIG. 5 is an exemplary schematic diagram showing a state in which the conventional cover is placed on the lower electrode;

FIG. 6 is an exemplary magnified cross-sectional view showing a state in which the cover is placed on the lower electrode;

FIG. 7 is an exemplary magnified cross-sectional view showing a state of the conventional cover and the lower electrode after processing of the plasma apparatus; and

FIG. 8 is an exemplary perspective view showing a state of the lower electrode after the processing using the conventional cover.

### DETAILED DESCRIPTION OF PREFERRED EMBODIMENTS

This invention was first described in Japanese Patent Application 2001-293188, hereby incorporated by reference in its entirety.

A cover for an electrode, a plasma apparatus utilizing the cover, and a method of fitting the cover to the electrode according to an embodiment of this invention will be described in detail with reference to the accompanying drawings.

The problems associated with a conventional cover used in a parallel-plate plasma etching apparatus, as an example of a plasma apparatus, will be explained in detail with reference to FIGS. 4-8.

A parallel-plate plasma etching apparatus utilizes an upper and a lower electrodes to generate plasma. As shown in FIG. 4, a lower electrode 16 includes a raised central portion 16a surrounded by a sidewall 16c and a peripheral portion 16b. More specifically, the peripheral portion 16b has an annular shape, and the central portion 16a has a disc-like shape, i.e., the shape of a workpiece (i.e., a semiconductor wafer) to be processed, and is disposed at the center of the peripheral portion 16b. The dimension, for example, a diameter, of the central portion 16a is smaller than the outer dimension of the peripheral portion 16b.

In other words, the main surface (i.e., upper surface) of the lower electrode 16 has a raised central portion 16a and a peripheral portion 16b. The central portion 16a is surrounded by a sidewall 16c, and the peripheral portion 16b is connected to the raised portion 16a by the sidewall 16c.

The lower electrode 16 is constructed with aluminum, and the main surface of the lower electrode 16 is coated with a protective coating by anodizing (i.e., alumite-coated), and is electrically insulated. An electrostatic film 32 is adhered on the central portion 16a of the main surface of the electrode 16. A sidewall protecting film 30 is attached over the sidewall 16c in order to enhance the insulation.

A cover for the lower electrode (hereinafter referred to as an electrode cover) 36 is a ring-shaped quartz plate having a predetermined thickness, and has an opening at the center thereof. In order to cover substantially the entire region of the peripheral portion 16b of the lower electrode 16, the opening is formed in a shape and a size nearly the same as that of the top surface of the central portion 16a.

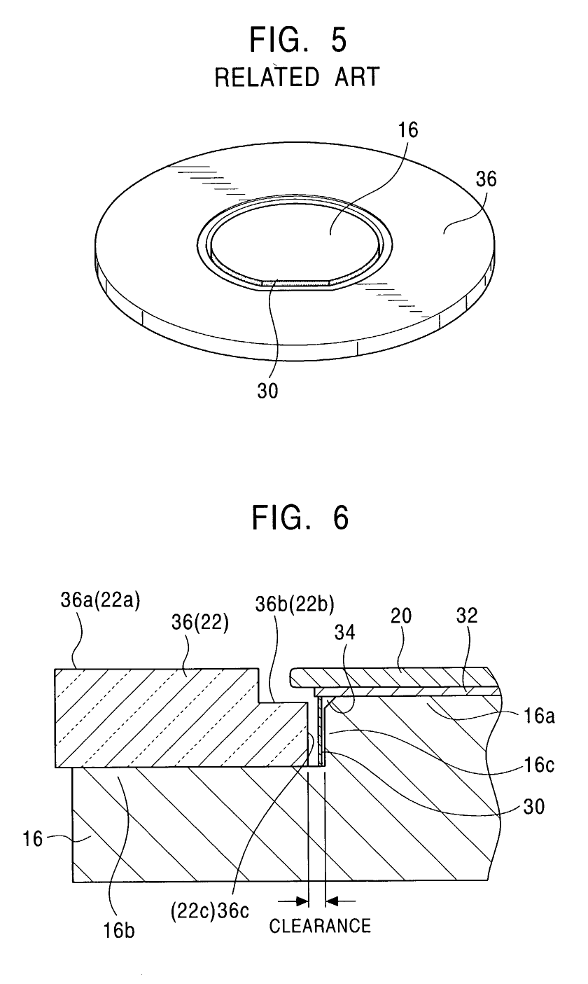

As shown in FIG. 4, the electrode cover 36 is fitted onto the lower electrode 16 from above such that the raised central portion 16a is inserted into the opening of the cover 36. Thus, as shown in FIG. 5, the electrode cover 36 is placed over the peripheral portion 16b of the lower electrode 16 such that the electrode cover 36 covers substantially the entire region of the peripheral portion 16b. A predetermined clearance must be provided between the sidewall 16c of the electrode 16 and the inner wall 36c of the cover 36, as shown in FIG. 6, so that the cover 36 can be fitted to the electrode 16 from above.

FIG. 6 is an exemplary magnified cross-sectional view showing a relationship between the cover 36, lower electrode 16 and a workpiece, such as a semiconductor wafer 20, placed on the central portion of the lower electrode 16. As shown in FIG. 6, the electrode cover 36 is fitted to the electrode 16 to cover the peripheral portion 16b of the electrode 16. The inner edge of the electrode cover 36 having the inner wall 36c surrounds the sidewall 16c of the electrode 16. A clearance is provided between the inner wall 36c of the electrode cover 36 and the sidewall 16c of the electrode 16.

The wafer 20 is electrically insulated from the lower electrode 18 by an electrostatic film 32, and is chucked by an electrostatic force. The electrostatic film 32 is, for example, a multi-layered film including a patterned conductive film layer (not shown) laminated between insulating films, such as polyimide films. An electrostatic force generated by applying an electric potential to the conductive film pattern chucks the back surface of the wafer 20. In other words, the electrostatic film 32 functions as an electrostatic chuck.

Thus, the central portion 16a of the lower electrode 16, having the electrostatic film 32 thereon, acts as a pedestal to support the back surface of the wafer 20. Thereby, the front surface of the wafer 20 is processed in the plasma apparatus.

A sidewall protecting film 30 for protecting the protective coating on the sidewall 16c of the electrode 16 is attached over the entire portion of the sidewall 16c by an adhesive 34 applied to a beveled portion formed at the periphery of the top surface of the central portion 16a of the electrode 16.

In this example, the dimension (or diameter) of the central portion 16a is almost identical to, but somewhat smaller than, that of the wafer 20. Therefore, the outer edge of the wafer 20 overhangs outwardly over the edge of the central portion 16a.

In order to prevent interference between the outer edge of the wafer 20 and the cover 36, the inner edge of the cover 36 is stepped. That is, the upper surface 36b near the inner wall 36c of the cover 36 is lowered relative to the upper surface 36a at portions remote from the inner wall 36c.

When the clearance between the sidewall 16c of the electrode 16 and the inner wall 36c of the cover is too small, the cover 36 may interfere with the sidewall protecting film 30 when fitting the cover 36 to the electrode 16. For example, the sidewall film 30 may be partially peeled during the fitting of the cover 36.

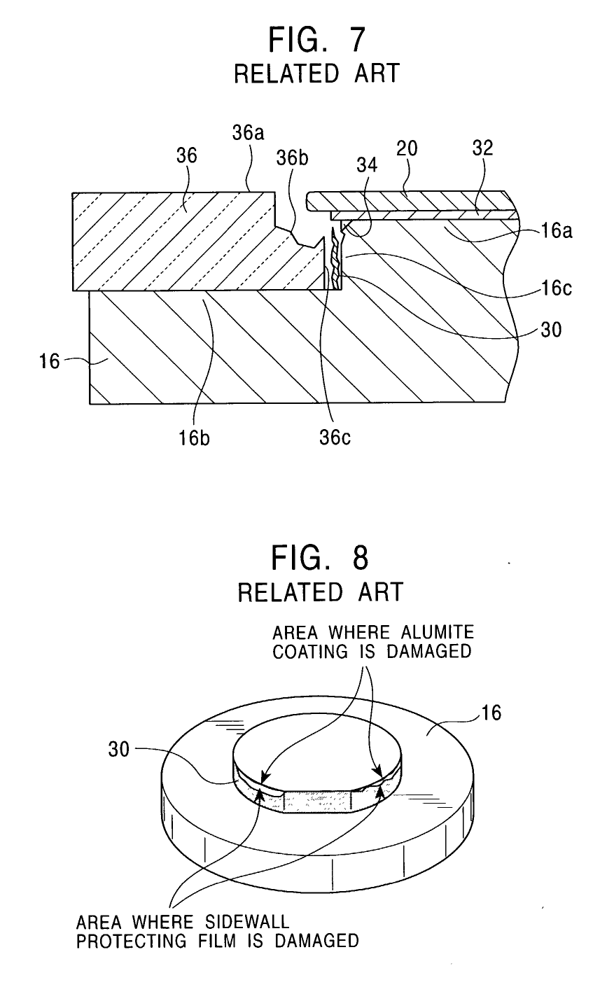

When the clearance is too large, on the other hand, the plasma flows around the edge of the semiconductor wafer 20 and into the space between the sidewall 16c of the electrode 16 and the inner wall 36c of the cover 36. As a result, the upper surface 36b and the inner wall 36c at the inner edge of the electrode cover 36 are damaged or etched during a repeated processing of a plurality of wafers 20. Further, the protecting film 30 on the sidewall 16c of the electrode 16 is also damaged as shown is FIG. 7.

When the inner wall 36c of the cover 36 is etched, the space between the inner wall 36c of the cover and the sidewall 16c of the electrode 16 widens. Furthermore, the etching of the sidewall protecting film 30 and the protective coating on the sidewall 16c of the electrode 16 proceeds more rapidly. As a result, the sidewall 16c of the electrode 16 is severely damaged as shown in FIG. 8.

Thus, when the clearance is too small and too large, the sidewall protecting film 30 may be damaged. Consequently, a cost for repairing the sidewall protecting film 30 is incurred.

Further, at least when the clearance is too large, the protective coating on the sidewall 16c of the electrode 36 may also be damaged and another cost for repairing the protective coating is incurred.

In addition, the cover 36 is conventionally constructed as a one-piece part. Therefore, the cover must be replaced as a whole when the upper surface 36b or the inner wall 36c at the inner edge of the cove is damaged, even though the remaining portions of the cover is not significantly damaged. Therefore, a high cost of replacement parts is incurred.

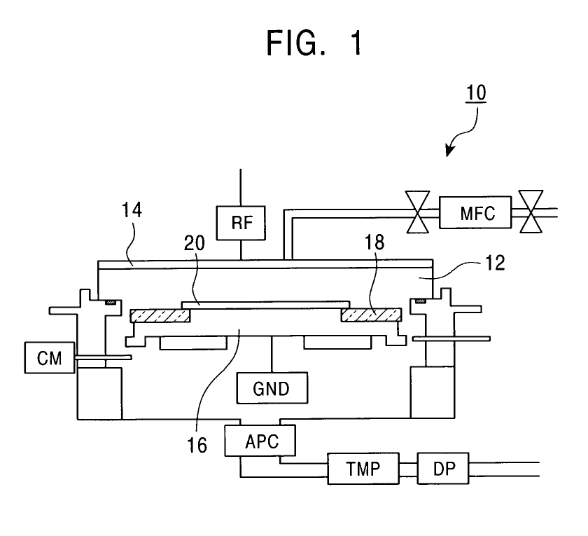

An electrode cover for an electrode and a plasma apparatus utilizing the cover, and a method of fitting the cover to the electrode according to an embodiment of this invention will be explained referring to FIGS. 1-4 and 6.

FIG. 1 is an exemplary schematic diagram showing a plasma apparatus 10 according to an embodiment of this invention. The apparatus is a parallel-plate plasma etching apparatus utilizing an upper electrode 14, lower electrode 16 and an electrode cover 18 for covering the peripheral portion of the lower electrode 16 according to an embodiment of this invention. The apparatus is used to process a surface of a workpiece, such as a semiconductor wafer 20, placed on the raised central portion (or pedestal) of the lower electrode 16.

The plasma etching apparatus 10 has a chamber 12 within which the upper electrode 14 and the lower electrode 16 are provided. A process gas is supplied into the chamber 12 through a mass flow controller MFC and is evacuated by a turbo molecular pump TMP and a dry pump DP. The gas pressure within the chamber 12 is monitored by a capacitance manometer CM, and is controlled to a desired value using an automatic pressure controller APC.

The lower electrode 16 is electrically connected to the ground GND, and a radio-frequency electric power is supplied to the upper electrode 14 from a radio-frequency power supply RF. Plasma of the process gas is generated in the space between the upper electrode 14 and the lower electrode 16. The plasma processes the surface of the wafer 20.

The size (i.e., diameter) of the lower electrode 16 is made larger than that of the wafer 20, so that the entire surface of the wafer is uniformly processed. As a result, the wafer 20 does not cover the peripheral portion of the lower electrode 16. Therefore, the electrode cover 18 is provided to cover the peripheral portion of the lower electrode 16.

The lower electrode 16 used in the plasma apparatus 10 is the same as previously explained referring to FIGS. 4 and 6.

That is, the lower electrode 16 has a raised central portion 16a surrounded by a sidewall 16c and a peripheral portion 16b (see FIG. 4). The central portion 16a is used as a pedestal on which the wafer 20 is placed. Therefore, the upper surface of the central portion is substantially flat. The dimension (or diameter) of the central portion 16a is almost the same as, but is smaller than, the dimension of the wafer 20.

The outer dimension (or diameter) of the peripheral portion 16c is larger than the dimension of the wafer 20. The surface of the peripheral portion 16c is substantially flat and is substantially parallel to the surface of the raised portion 16a. Therefore, the main surface (or upper surface) of the lower electrode 16, including the surfaces of the raised portion 16a and the peripheral portion 16c, effectively forms parallel-plate electrodes together with the upper electrode 14.

The main surface of the lower electrode 16 is anodized, and a sidewall protecting film 30 for protecting the protective coating is provided over the entire portion of the sidewall 16c by an adhesive 34 applied to a beveled portion formed at the periphery of the upper surface of the central portion 16a (see FIG. 6).

Construction of the electrode cover 18 according to the embodiment of this invention will be described in detail. When placed over the lower electrode 16, the electrode cover 18, has essentially the same structure as that of the conventional cover 36 shown in FIG. 4.

That is, the cover 18 is a ring-shaped quartz plate having a predetermined thickness. The electrode cover 18 is placed over the peripheral portion 16b of the lower electrode 16 and prevents the peripheral portion 16b of the lower electrode 16 from being etched by the plasma. The electrode cover 18 also serves as a focus ring for focusing the plasma in an area between the upper electrode 14 and the lower electrode 16. The electrode cover 18 has an opening whose shape and size are similar to those of the central portion 16a of the lower electrode 16, leaving a predetermined clearance around the sidewall 16c.

However, the electrode cover 18 according to the embodiment of this invention is constructed with a plurality of divided sections, in contrast with the one-piece construction of the conventional electrode cover 36.

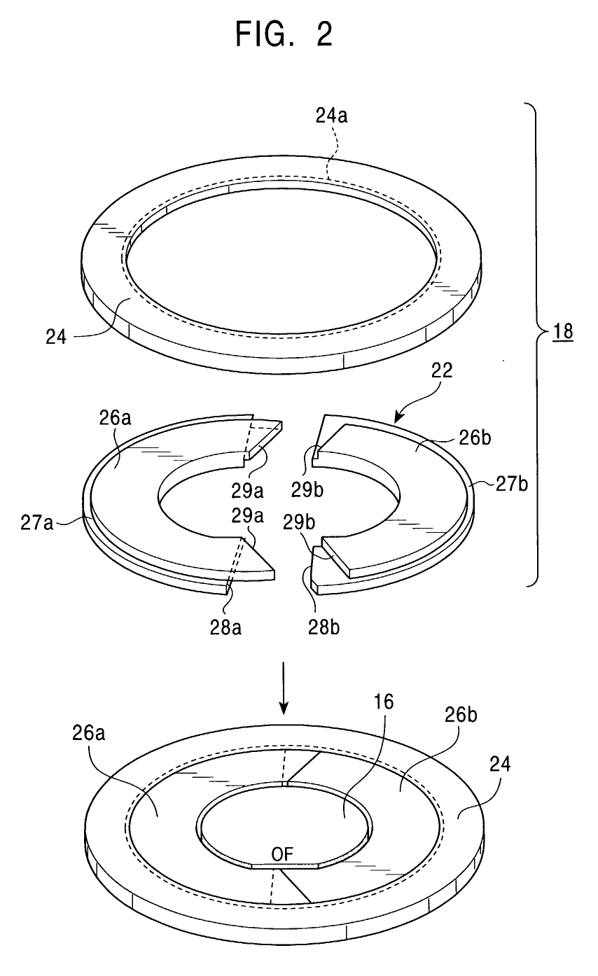

FIG. 2 is an exemplary schematic diagram showing the electrode cover 18 according to the embodiment of this invention. The electrode cover 18 includes an inner ring (or inner portion) 22 and an outer ring (or outer portion) 24. The inner ring 22 covers a predetermined region (or inner region) of the peripheral portion 16b that is close to the central portion 16a of the lower electrode 16. The outer ring 24 covers the remaining region (outer region) of the peripheral portion 16b that cannot be covered by the inner ring 22. In other words, the cover 18 shown in FIG. 2 is separated into two concentric portions in the radial direction.

The inner ring 22 shown in FIG. 2 is further divided into two arc-shaped sections, ring sections 26a and 26b, in the circumferential direction. In other words, the inner ring 22 is constructed by combining the ring sections 26a and 26b together.

Each of the ring sections 26a and 26b covers half of the inner region of the peripheral portion 16b. In this embodiment, each of the ring sections 26a and 26b covers a predetermined portion of the inner region of the peripheral portion 16b of the electrode.

That is, the inner region is separated into two portions relative to the flat portion of the sidewall 16c (marked as “OF” in FIG. 2), which corresponds to the orientation flat of the wafer to be placed on the central portion 16a. One of the ring sections 26a covers one of the two portions (the left half in FIG. 2) of the inner region of the peripheral portion 16b of the electrode 16. The other ring section 26b covers remaining half (the right half in FIG. 2) of the inner region of the peripheral portion 16b.

On the other hand, the outer ring 24 is a ring-shaped quartz plate formed of a single section. That is, the outer ring 24 itself is an outer section to be combined with the inner ring sections 26a and 26b to form the electrode cover 18.

As shown in FIG. 2, the upper layer and the lower layer of each of the ring sections 26a and 26b and the outer ring 24 according to this embodiment have specific structures. Such structures are useful to properly combine the divided sections 26a, 26b and 24.

First, projections or flanges 27a and 27b are formed at the outer periphery of the lower layers of the ring sections 26a and 26b, respectively. Moreover, a projection or a flange 24a is formed at the inner periphery of the upper layer of the outer ring 24. When the cover 18 is fitted to the peripheral portion 16b of the electrode 16, the flange 24a of the outer ring 24 overlaps with the flanges 27a and 27b of the ring sections 26a and 26b. Thus, the outer ring 24 is combined with the inner ring 22 formed by combining the ring sections 26a and 26b with an appropriate positional relationship between the rings.

Further, the lower layers of the connecting portions 28a and 28b at the ends of the ring sections 26a and 26b, respectively, are formed perpendicularly to the sidewall 16c of the electrode 16. Thus, the lower layers of the ring sections 26a and 26b have shapes such that the inner ring is evenly divided into two sections.

On the other hand, the upper layers of the connecting portions 29a at the ends of the ring section 26a are formed at an angle of 60° with respect to the sidewall 16c of the electrode 16 (at an angle of 30° from a reference line that is perpendicular to the sidewall 16c). That is, the upper layers of the connecting portions 29a of the ring section 26a protrude from the lower layers of the connecting portions 28a.

In addition, the upper layers of the connecting portions 29b at the ends of the upper layer of the ring section 26b are formed at an angle of 120° with respect to the sidewall 16c of the electrode 16 (at an angle of 30° from a reference line that is perpendicular to the sidewall 16c). That is, the upper layers of the connecting portions 29b of the ring section 26b pulled back from lower layers of the connecting portions 28b. Thus, the lower layers of the connecting portions 28b of the ring section 26b protrude from the upper layers of the connecting portions 28b.

When the inner ring 22 according to this embodiment is fitted to the lower electrode 16, the projections in the upper and lower layers of the connecting portions of the ring sections overlap with each other. Specifically, the projection in the upper layer 29a of one of the ring sections 26a overlap over the projection in the lower layer 28b of the other one of the ring sections 26b. Accordingly, the ring sections 26a and 26b are combined with an appropriate positional relationship between them to form the inner ring 22.

The angles of the lower layers of the connecting portions 28a and 28b and the upper layers of the connecting portions 29a and 29b with respect to the sidewall 16c of the electrode 16 are not limited. However, in the case in which the inner ring 22 is divided into two sections as in this embodiment, the lower layers of the connecting portions 28a and 28b are preferably formed perpendicularly to the sidewall 16c of the electrode 16. Thereby, the ring sections 26a and 26b can be easily fitted to the lower electrode 16.

Furthermore, the upper layers of the connecting portions 29a and 29b are preferably formed at an angle of around 30° with respect to a reference line that is perpendicular to the sidewall 16c of the electrode 16. Such relatively small angle is preferable to prevent the projections from breaking during cleaning or carrying of the divided sections.

In the embodiment, the upper layers of the connecting portions 29a of one of the ring sections 26a protrude from the lower layer thereof, and the upper layers of the connection portions 29b of the other one of the ring sections 26b pull back from the lower layer thereof. However, this invention is not limited to this construction. For example, in each of the ring sections 26a and 26b, the upper layer may protrude from the lower layer at one of the connecting portions, while the upper layer pulls back at the other one of the connecting portions.

Fitting of the electrode cover 18 to the lower electrode 16 may be performed as follows.

First, the ring sections 26b and 26a are fitted from the sides of the central portion 16a and are placed at predetermined positions. That is, the divided ring sections 26a and 26b are moved toward the sidewall 16c along the peripheral portion 16b of the electrode 16 so that they are combined or connected with each other to form the inner ring 22.

In practice, the divided ring sections 26a and 26b may be put on the peripheral portion 16b of the lower electrode 16, and pushed and slid along the peripheral portion 16c toward the sidewall 16c so that the connecting portions 29a and 28b overlap with each other. Thereby, ring sections 26a and 26b are combined to form the inner ring 22.

When the divided ring sections 26a and 26b are formed of a fragile material such as quartz, it is better to fit the divided ring sections one after the other. At first, for example, the ring section 26b may be fitted to the lower electrode 16. Then, the ring section 26a may be fitted to the lower electrode, on which the other ring section 26b is already fitted, so that the connecting portions 29a of the ring section 26a overlap over the corresponding connecting portions 28b of the ring section 26b.

Then, the outer ring 24 is fitted from above such that the flange 24a overlaps with the flanges 27a and 27b of the inner ring 22. Accordingly, as shown in the bottom of FIG. 2, the electrode cover 18 is fitted to the peripheral portion 16b of the lower electrode 16 such that substantially the entire region of the peripheral portion 16b is covered.

The lower electrode 16 used in this embodiment is the same as that shown in FIG. 6. The dimension of the central portion 16a is slightly smaller than that of the semiconductor wafer 20 to be placed on the central portion. Therefore, as shown in FIG. 6, the peripheral edge of the semiconductor wafer 20 protrudes slightly from the central portion 16a of the lower electrode 16.

The electrode cover 18 according to this embodiment differs from the conventional cover 36 in that it is divided in both the radial direction and the circumferential direction. When the cover 18 is fitted to the lower electrode 16, however, the shape and function of the cover are basically the same as those of the conventional cover 36. In fact, the positional relationship between the inner ring 22 of the cover 18, the lower electrode 16 and the wafer 20 supported on the central portion 16a of the electrode 16 is basically the same as that of the conventional case shown in the magnified cross-sectional view of FIG. 6.

As will be explained later, however, the clearance between the inner wall of the inner ring 22 according to this embodiment and the sidewall 16c of the electrode 16 can be markedly reduced compared to the conventional cover 36.

In the following paragraphs the features common to the conventional cover 36 and the electrode cover 18 according to this embodiment will be explained. And then the difference between them will be explained. For the explanation of the common features, FIG. 6, which is used for the explanation of the conventional cover 36, will be commonly used. In FIG. 6, the inner ring 22 of the cover 18 according to this embodiment is shown with reference numerals in parentheses.

At first, similarly to the conventional electrode cover 36, the thickness of the electrode cover 18 is determined such that, when the cover 18 is fitted on the lower electrode 16, the height of the upper surface 18a of the cover 18 and that of the semiconductor wafer 20 placed on the raised portion 16a of the lower electrode 16 are approximately the same. That is, both of the inner ring 22 and the outer ring 24 may have the same thickness as that of the conventional cover 36 except for their connecting portions.

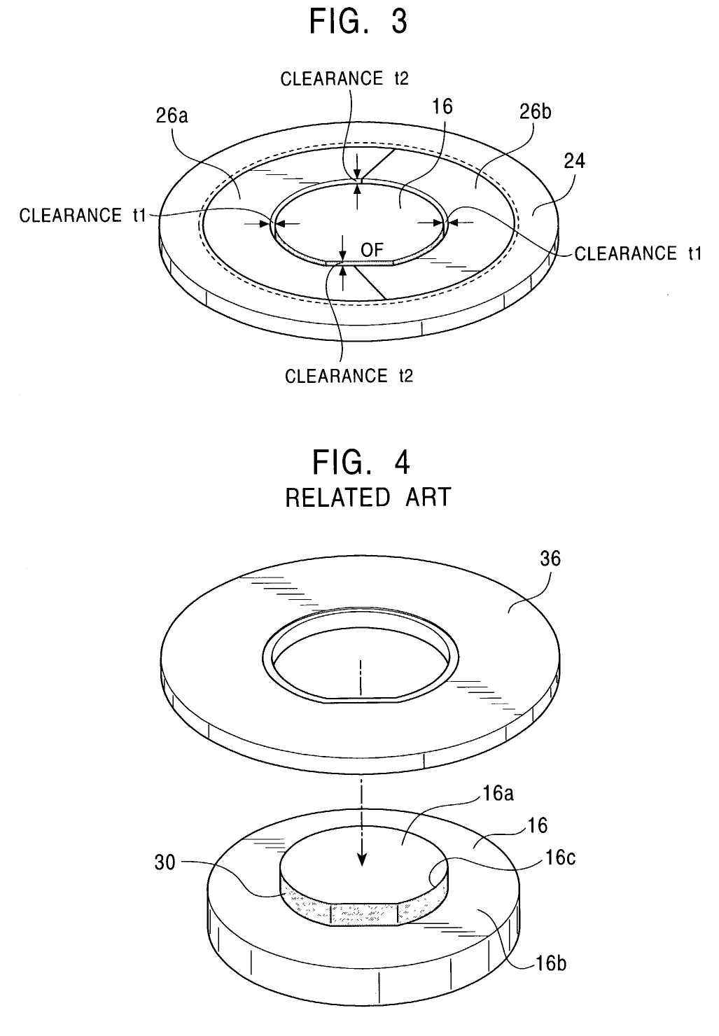

Although not shown in FIGS. 2 and 3 for simplicity, the inner edge of the inner ring 22 that surrounds the sidewall 16c of the electrode 16 has a stepped structure as shown in FIG. 6. That is, similar to the conventional cover 36, the height (thickness) of the inner ring 22 is lowered at the region 22b close to the inner wall 22c (shown in FIG. 6). Accordingly, the upper surface 22b at the inner edge of the inner ring 22 of the electrode cover 18 of this embodiment is lower than the upper surface of the central portion 16a (or, to be precise, the upper surface of the electrostatic film 32) of the lower electrode 16. That is, the upper surface 22b of the inner edge of the inner ring 22 is lower than the back surface of the wafer 20 supported on the central portion 16a of the electrode 16.

Therefore, the inner edge of the inner ring 22 of the electrode cover 18 is prevented form coming into contact with the back surface of the outer edge of the wafer 20. Because the inner ring 22 of the cover 18 does not come into contact with the semiconductor wafer 20, chipping of the wafer and generation of particles are prevented.

However, the present invention is not limited to this embodiment as long as the shape of the electrode cover is determined such that it does not come into contact with the semiconductor wafer 20 placed on the central portion 16a of the lower electrode 16. For example, when the size of the central portion 16a is large enough and the peripheral edge of the semiconductor wafer 20 does not protrude from the central portion 16a, the height of the upper surface of the inner ring 22 may be the same as or higher than that of the central portion 16a of the electrode 16. In other words, the thickness of the inner ring 22 may be the same as or larger than the height of the sidewall 16c.

Now, the difference between the electrode cover 18 according to this embodiment and the conventional cover 36 will be explained.

As described above, when the electrode cover 18 according to this embodiment is fitted to the lower electrode 16, the ring sections 26b and 26a of the inner ring 22 are fitted from the sides of the central portion 16a. Accordingly, as shown in FIG. 3, clearances t1 between the sidewall 16c of the electrode 16 and the inner walls of the ring sections 26a and 26b at the central regions can be arbitrary made close to zero. Clearances t2 between the sidewall 16c of the electrode 16 and the inner walls of the ring sections 26a and 26b at the connecting portions can also be reduced compared to the case of the conventional ring 36.

Because the conventional electrode cover 36 shown in FIG. 4 must be fitted to the lower electrode 16 from above, a clearance of about 0.5 mm is required (both the clearances t1 and t2 must be 0.25 mm). On the other hand, in the electrode cover 18 according to this embodiment shown in FIGS. 2 and 3, the ring sections 26a and 26b are fitted from the sides. Therefore, the clearance can be reduced to 0.1 mm or less (e.g., the clearance t1≈0 and the clearance t2 =0.05 mm).

In this embodiment, the central portion 16a of the electrode 16 has a shape similar to the semiconductor wafer 20 to be placed on the central portion 16a. That is, the central portion 16a has a generally circular outer edge with a flat portion denoted by OF in FIGS. 2 and 3. The flat portion OF corresponds to the orientation flat of the semiconductor wafer 20 to be placed on the central portion 16a.

The position in the circumferential direction at which the inner ring 22 is divided is determined using this flat portion OF as a reference. Specifically, the inner ring 22 is divided such that both of the ring sections 26a and 26b have a region corresponding to the flat portion OF.

In this case, the ring sections 26a and 26b can be fitted to the lower electrode 16 by sliding them in the direction generally parallel to the flat portion OF of the central portion 16a. Accordingly, the clearances at positions 90° away from the flat portion OF (t1 in FIG. 3) can be made arbitrarily close to zero.

Alternatively, the inner ring 22 may also be divided by using the positions 90° away from the flat portion OF of the central portion 16a as a reference. In this case, only one of the ring sections 26a and 26b has a region corresponding to the flat portion OF. When fitting the ring sections 26a and 26b divided in this manner to the lower electrode 16, they can be fitted by sliding them in the direction generally perpendicular to the flat portion OF of the central portion 16a. Accordingly, the clearance at the flat portion OF corresponding to the orientation flat (t2 in FIG. 3) can be made arbitrarily close to zero.

When a semiconductor wafer having a notch instead of an orientation flat is used as the workpiece 20, the central portion 16a of the electrode 16 may be constructed to have a circular outer edge without a flat portion. In this case, the position in the circumferential direction at which the inner ring 22 is divided is determined arbitrary.

Thus, in the electrode cover 18 of the invention, the ring sections 26b and 26a of the inner ring 22 are fitted to the lower electrode 16 from the sides. Therefore, the sidewall protecting film 30 attached over the sidewall 16c of the lower electrode 16 can be prevented from being damaged. In addition, because the clearance between the inner wall of the electrode cover 18 and the sidewall 16c of the electrode 16 can be reduced, etching of the sidewall protecting film 30 and the protective coating of the sidewall of the lower electrode 16 can be suppressed significantly.

The sidewall protecting film 30 attached over the sidewall 16c of the electrode 16 is not always necessary. Accordingly, the electrode cover according to the invention may also be fitted to an electrode that does not have a sidewall protecting film.

In the embodiment described above, the electrode cover 18 is placed on the surface of the peripheral portion 16b of the lower electrode 16. The cover keeps a fixed positional relationship with the electrode by the friction between the lower surface of the cover and the upper surface of the peripheral portion of the electrode during the operation, or a repeated processing of a plurality of workpieces, of the plasma apparatus. Similarly, the divided sections of the cover keep a fixed positional relationship with each other by the friction between the divided sections and the peripheral portion and between the connecting portions of the divided sections during the operation of the plasma apparatus.

Alternatively, the cover may be firmly fixed to the lower electrode with screws or other fixing means.

Note that, contrary to the movable electrode cover 3a disclosed in Japanese Unexamined Patent Application Publication No. 62-78845 (JP 62-78845), the electrode cover 18 according to the embodiment described above does not move after it is fitted onto the peripheral portion 16b of the electrode 16. That is, the electrode cover 3a of JP 62-78845 must be movable so that the cover 3a holds the side edge of the wafer 1 placed on the electrode 2. In the plasma apparatus 10 of the embodiment described above, on the other hand, an electrostatic chuck chucks the workpiece 20 onto the central portion 16a of the lower electrode 16 during the processing within the apparatus. Accordingly, it is not necessary for the cover 18 to hold the outer periphery or the side edge of the workpiece 20 placed on the central portion 16a of the electrode 16.

Therefore, the cover 18 according to the embodiment of this invention may keep a fixed positional relationship with the electrode 16 during the operation of apparatus 10. In other words, each of the divided sections 26a, 26b and 24 may keep a fixed positional relationship with each other and with the lower electrode 16 during the operation of the apparatus 10. As a result, there is no problem of generation of particles due to the movement of the divided sections.

Also contrary to the electrode cover 3a disclosed in JP 62-78845, the upper surface 22b of the inner edge of the inner ring 22 formed by combining the inner ring sections 26a and 26b according to the embodiment describe above is lower than the back surface of the workpiece supported on the central portion 16a of the electrode 16. That is, the upper surface of the electrode cover 3a of JP 62-78845 must be higher than the back surface of the wafer 1 so that the cover 3a holds the side edge of the wafer 1. In the plasma apparatus 10 of the embodiment described above, on the other hand, it is not necessary for the cover 18 to hold the outer periphery or the side edge of the workpiece 20 supported on the central portion 16a of the electrode 16.

Therefore, the upper surface 22b of the inner edge of the inner ring 22 of the cover 18 according to the embodiment of this invention may be made lower than the back surface of the workpiece 20 supported on the central portion 16a of the electrode 16. As a result, the inner edge of the inner ring 22 of the electrode cover 18 according to the embodiment of this invention may be prevented from come into contact with the back surface of the outer edge of the workpiece 20. Therefore, as explained previously, there is no problem of chipping of the workpiece and the generation of particles.

In the embodiment describe above, the connecting portions of the ring sections 26a and 26b of the inner ring 22 and the connecting portions of the inner ring 22 and the outer ring 24 have the step-like shape in the cross section. In other words, the upper and lower layers of the divided sections of the cover overlap with each other at the connection portions. As a result, the plasma is prevented from flowing through the connecting portions of the electrode cover 18 toward the surface of the lower electrode 16. Therefore, an abnormal electric discharge is prevented.

In the embodiment described above, the electrode cover 18 is also divided in the radial direction. Therefore, when the upper surface of the inner ring 22 is etched at the region close to the outer edge of the central portion 16a of the lower electrode 16, only the inner ring 22 can be replaced. The outer ring 24 can be used continuously. Therefore, a cost for replacement parts can be reduced.

For this purpose, the inner ring 22 should preferably have a dimension along the radial direction sufficient to cover the entire region in which the surface of the cover is significantly etched.

In the embodiment described above, the electrode cover for the lower electrode of the dry etching apparatus for processing semiconductor wafers is described as an example. However, this invention may also be applied to the upper electrode, or to various other types of electrodes used in various types of plasma apparatus.

In the embodiment described above, all of the divided sections of the electrode cover 18 are constructed with quartz. However, the material for the electrode cover is not limited to insulating materials such as quartz. Conductive materials such as carbon, silicon, etc., may also be used in accordance with the intended function of the cover.

Further, all of the divided sections of the electrode cover need not be constructed with the same material. For example, the outer and the inner ring may be constructed with different insulating materials. Or, one of the outer and the inner rings may be constructed with an insulating material, while the other one may be constructed with a conductive material.

In the embodiment described above, the inner ring is divided into two sections in the circumferential direction. However, the inner ring may also be divided into three or more sections. As the number of divided sections increases, the clearance between the sidewall of the electrode and the inner wall of the cover can be made closer to zero. However, the cost of the cover increases as the number of division increases.

In the embodiment described above, the cover 18 is placed directly on the peripheral portion 16b of the lower electrode 16. It is also possible to insert an underlying member between the cover and the peripheral portion of the electrode, when, for example, the height of the sidewall is higher than the thickness of the cover.

In the embodiment described above, the peripheral portion 16b of the lower electrode 16 is generally flat. The generally flat peripheral portion is useful to place the divided sections of the cover on it. However, shape of the electrode changes depending on the design of the plasma apparatus.

For example, the peripheral portion of the electrode may be divided by a step into the first region adjacent to the central portion and a second region far from the central portion and lower than the first region. In this case, an underlying ring may be placed on the second portion, thereby making a combined surface including the first region and the upper surface of the underlying ring generally flat. Then, the cover according to the invention including divided inner sections and an outer section may be placed on the combined surface.

In the embodiment described above, the lower electrode 16 is constructed with aluminum. However, various other materials may be used to construct the lower electrode. Moreover, the lower electrode may be constructed with two or more parts constructed with same or different materials. For example, the central portion of the lower electrode, which acts as a pedestal to support a workpiece, may be constructed separately from the remaining part, so that the lower electrode can be constructed by combining the parts.

In the embodiment described above, the electrostatic film 32, which is formed by laminating a conductive pattern layer between polyimide films, is used as an electrostatic chuck to hold a workpiece. The electrostatic chuck may be constructed with other insulating materials such as various ceramic materials.

The boundaries between the divided sections of the inner ring serve as grooves that divide a film of deposited material formed during the operation of the plasma apparatus. Accordingly, the film of deposited material is prevented from peeling and the generation of particles is prevented. When the number of divided sections of the inner ring increases, an effect similar to those obtained by a focus ring with grooves disclosed in the U.S. patent application Ser. No. 09/449,347 (now U.S. Pat. No. 6,447,853) may be accomplished.

In the case in which the number of divided sections is small, a plurality of grooves may be formed in the upper surface of the inner ring at the region close to the outer edge of the central portion of the lower electrode.

The electrode cover, apparatus utilizing the cover, and method of fitting the cover to the electrode according to the present invention is constructed as explained in the foregoing descriptions. While the invention has been described with reference to preferred embodiments thereof, it is to be understood that the invention is not limited to the preferred embodiments or constructions. To the contrary, the invention is intended to cover various modifications and equivalent arrangements. In addition, while the various elements of the preferred embodiments are shown in various combinations and configurations, which are exemplary, other combinations and configurations, including more, less or only a single element, are also within the spirit and scope of the invention.

What is claimed is:

1. A cover for covering a peripheral portion of an electrode of a plasma apparatus, the electrode having a main surface including a raised central portion surrounded by a sidewall, and the peripheral portion connected to the central portion by the sidewall, the cover comprising:
a plurality of divided sections,
wherein the cover, when fitted to the electrode, has an inner edge that surrounds the sidewall of the electrode and that is formed by combining the divided sections, the divided sections keeping a fixed positional relationship with each other during an operation of the plasma apparatus.

2. The cover according to claim 1, wherein the electrode further comprises a protecting film attached over the sidewall.

3. The cover according to claim 1, wherein the divided sections have projections, and the divided sections are combined such that the projections of adjacent ones of the divided sections overlap with each other.

4. A cover for covering a peripheral portion of an electrode of a plasma apparatus, the electrode having a main surface including a raised central portion surrounded by a sidewall and the peripheral portion connected to the central portion by the sidewall, the central portion supporting a back surface of a workpiece during the processing within the plasma apparatus and having a dimension smaller than that of the workpiece, the cover comprising:
a plurality of divided sections,
wherein the cover, when fitted to the electrode, has an inner edge that surrounds the sidewall of the electrode and formed by combining the divided section, the inner edge having an upper surface lower than the back surface of the workpiece supported on the central portion of the electrode.

5. The cover according to claim 4, wherein the electrode further comprises a protecting film attached over the sidewall.

6. The cover according to claim 4, wherein the divided sections have projections, and the divided sections arc combined such that the projections of adjacent ones of the divided sections overlap with each other.

7. A cover for covering a peripheral portion of an electrode of a plasma apparatus, the electrode having a main surface including a raised central portion surrounded by a sidewall and the peripheral portion connected to the central portion by the sidewall, the cover comprising:
a plurality of divided sections including a plurality of inner sections and an outer section,
wherein:
the cover, when fitted to the electrode, includes an inner portion having an inner edge that surrounds the sidewall of the electrode and an outer portion;
the inner edge is formed by combining the inner sections; and
the outer portion is formed by combining the outer section to the combined inner sections.

8. The cover according to claim 7, wherein each of the inner sections and the outer section is formed of an insulating material.

9. The cover according to claim 7, wherein the inner sections and the outer section are formed of a same material.

10. The cover according to claim 7, wherein each of the inner sections and the outer section has a projection, and the outer section is combined to the inner sections such that the projection of the outer section overlaps with the projections of the inner sections.

11. A plasma apparatus for processing a workpiece, comprising:
an electrode having a main surface including a raised central portion for supporting the workpiece during the processing, a sidewall that surrounds the central portion and a peripheral portion connected to the central portion by the sidewall; and
a cover that covers the peripheral portion of the main surface of the electrode and having an inner edge that surrounds the sidewall of the electrode, the cover further comprising a plurality of divided sections,
wherein the inner edge of the cover is formed by combining the divided sections, and the divided sections keep a fixed positional relationship with each other during an operation of the plasma apparatus.

12. The apparatus according to claim 11, wherein the electrode further comprises a protecting film attached over the sidewall.

13. The apparatus according to claim 11, wherein the divided sections of the cover have projections, and the divided sections are combined such that the projections of adjacent ones of the divided sections overlap with each other.

14. A plasma apparatus for processing a workpiece, comprising:
an electrode having a main surface including a raised central portion for supporting a back surface of the workpiece, a sidewall that surrounds the central portion and a peripheral portion connected to the central portion by the sidewall; and
a cover that covers the peripheral portion of the main surface of the electrode and having an inner edge that surrounds the sidewall of the electrode, the cover further comprising a plurality of divided sections,
wherein:
the central portion of the electrode has a dimension smaller than that of the workpiece; and
the inner edge of the cover is formed by combining the divided sections and the inner edge has an upper surface lower than the back surface of the workpiece supported on the central portion of the electrode.

15. The apparatus according to claim 14, wherein the electrode further comprises a protecting film attached over the sidewall.

16. The apparatus according to claim 14, wherein the divided sections of the cover have projections, and the divided sections are combined such that the projections of adjacent ones of the divided sections overlap with each other.

17. A plasma apparatus for processing a workpiece, comprising:
an electrode having a main surface including a raised central portion for supporting the workpiece, a sidewall that surrounds the central portion and a peripheral portion connected to the central portion by the sidewall; and
a cover that covers the peripheral portion of the main surface of the electrode and having an inner edge that surrounds the sidewall of the electrode, the cover further comprising a plurality of divided sections including a plurality of inner sections and an outer section,
wherein the inner edge of the cover is formed by combining the divided inner sections and the outer section is combined to an outside of the combined inner sections.

18. The apparatus according to claim 17, wherein each of the inner sections and the outer section of the cover is formed of an insulating material.

19. The apparatus according to claim 17, wherein the inner sections and the outer sections of the cover are formed of a same material.

20. The apparatus according to claim 17, wherein each of the inner sections and the outer section of the cover has a projection, and the outer section is combined to the inner sections such that the projection of the outer section overlaps with the projections of the inner sections.

21. A method of fitting a cover to an electrode of a plasma apparatus, the electrode having a main surface that includes a raised central portion surrounded by a sidewall and a peripheral portion connected to the central portion by the sidewall, the method comprising the steps of:
providing a plurality of divided sections for the cover; and
fitting the cover to the electrode by moving the plurality of divided sections toward the sidewall of the electrode so that the plurality of divided sections arc combined with each other to form an inner edge of the cover that surrounds the sidewall of the electrode.

22. The method according to claim 21, wherein the cover is fitted to the electrode such that the plurality of divided sections keep a fixed positional relationship with each other during an operation of the plasma apparatus.

23. The method according to claim 21, wherein:
the central portion of the electrode supports a back surface of a workpiece during a processing within the plasma apparatus, the central portion has a dimension smaller than that of the workpiece; and
the inner edge of the cover fitted to the electrode has an upper surface lower than the back surface of the workpiece supported on the central portion of the electrode.

24. The method according to claim 21, wherein:
the providing further provides an outer section of the cover; and
the fitting further includes combining the outer section to the combined sections to form an outer portion of the cover.

25. The method according to claim 21, wherein the plurality of divided sections are moved toward the sidewall of the electrode along the peripheral portion of the main surface of the electrode.

26. The method according to claim 21, wherein:
the central portion of the electrode has a circular outer edge with a flat portion;
the plurality of divided sections of the cover includes s first and a second section each having an edge corresponding to the flat portion of the outer edge of the central portion; and
said moving the plurality of divided sections includes moving each of the first and the second sections in a direction generally parallel to the flat portion.

27. The method according to claim 21, wherein:
the central portion of the electrode has a circular outer edge with a flat portion;
the plurality of divided sections of the cover includes a first section having an edge corresponding to the flat portion of the outer edge of the central portion; and
said moving the plurality of divided sections includes moving the first section in a direction generally perpendicular to the flat portion.
